(19) United States
(12) Patent Application Publication
(10) Pub. No.: US 2025/0379157 A1
(43) Pub. Date: Dec. 11, 2025

(54) LABEL SUPPORT STRUCTURE INCLUDING A FILLER MATERIAL

(71) Applicant: Micron Technology, Inc., Boise, ID (US)

(72) Inventors: Rachelle THOREN, Nampa, ID (US); Mark A. TVERDY, Boise, ID (US); Bradley Russell BITZ, Taichung City (TW)

(21) Appl. No.: 19/174,149

(22) Filed: Apr. 9, 2025

Related U.S. Application Data
(60) Provisional application No. 63/657,499, filed on Jun. 7, 2024.

(51) Int. Cl. H01L 23/544; H01L 23/373; H01L 23/552

(52) U.S. Cl. CPC H01L 23/544; H01L 23/3733; H01L 23/552

(57) ABSTRACT

Implementations described herein relate to various semiconductor device assemblies. In some implementations, a semiconductor device assembly includes a substrate populated with one or more semiconductor packages and a label support structure that includes an expandable filler material over the substrate.

### CROSS-REFERENCE TO RELATED APPLICATION

This Patent application claims priority to U.S. Provisional Patent Application No. 63/657,499, filed on Jun. 7, 2024, entitled “LABEL SUPPORT STRUCTURE INCLUDING A FILLER MATERIAL,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a module having a label support structure that includes a filler material.

### BACKGROUND

An electronic system assembly, such as a memory module, may include multiple semiconductor packages electrically coupled to a carrier substrate (e.g., circuit substrate). The electronic system assembly may further include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphical content processing unit (GPU), a microprocessor, and/or a microcontroller), control units (e.g., a microcontroller, a memory controller, and/or a power management controller), or one or more other electronic components.

A label may be affixed to the electronic system assembly for tracking and/or consumer use purposes. The label may include textual content (e.g., part descriptions, part numbers, manufacturing dates), barcodes, quick response (QR) codes, and/or graphical content, among other examples.

### BRIEF DESCRIPTION OF THE DRAWINGS

FIG. 1 is an example integrated assembly including a label support structure described herein.

FIG. 2 includes diagrammatic views of example implementations of a label support structure described herein.

FIG. 3 is a flowchart of an example method of forming an integrated assembly or memory device having a label support structure including a filler material.

FIG. 4 is a flowchart of an example method of forming an integrated assembly or memory device having a label support structure including a filler material.

FIG. 5 is a flowchart of an example method of forming an integrated assembly or memory device having a label support structure including a filler material.

FIGS. 6A-6E are diagrammatic views showing formation of an integrated assembly having a label support structure including a filler material at example process stages of an example process of forming the integrated assembly.

FIGS. 7A-7D are diagrammatic views showing formation of an integrated assembly having a label support structure including a filler material at example process stages of an example process of forming the integrated assembly.

FIG. 8 is a diagram of an example memory device that may be manufactured using techniques described herein.

### DETAILED DESCRIPTION

In the area of electronic hardware, particularly module assemblies such as solid-state drives (SSDs) and memory modules (modules), product identification and certification play crucial roles. Labels affixed to such devices carry essential information for tracking, compliance with standards, and customer requirements. However, the miniaturization of components and the use of varied layouts present significant challenges to label placement and readability. As components are made smaller and stacked to reduce footprint, the resulting differences in component heights create an uneven surface, complicating label adherence and scanning. This uneven topography of module assemblies impedes the straightforward application of standardized labels, leading to issues with automated optical inspections and the ability of machines to reliably read critical data encoded on labels, such as QR codes.

Facing the compounding issue of needing to maintain label quality and content comprehensiveness while adhering to size constraints, the industry finds it challenging to produce adequately labeled module assemblies without incurring additional costs and manufacturing complexities. These challenges can extend even further to include a need for enhanced thermal and electrical performance.

Some implementations described herein provide a module assembly that includes a label support structure formed from a filler material. The label support structure may conform to an uneven topography of the module assembly and provide a substantially planar surface that is suitable for label adhesion. The label support structure may include advanced expandable filler materials such as graphene aerogel, ceramic foam, or polyimide foam, and include performance enhancements such as improved thermal conductivity or electromagnetic interference (EMI) shielding.

The label support structure may include an interface layer that is designed to be chemically or mechanically removable to facilitate easy label replacement. Formation of the label support structure may leverage liquid dispensing that naturally self-levels, with subsequent curing processes initiated by chemical agents or exposure to ultraviolet light to solidify and achieve the substantially planar surface.

The label support structure may improve aspects of affixing a label to a module assembly, ensuring label flatness and readability regardless of the physical anomalies of underlying semiconductor packages. The label support structure also allows for functional integration, such as thermal management or EMI shielding, which leverages the physical properties of the filler material.

The label support structure may enable manufacturers to adhere to labeling standards required for content and certifications without altering the component layout or necessitating major redesigns of substrates (e.g., printed circuit boards) specifically for labeling purposes. Additionally, the label support structure may contribute to manufacturing efficiencies by enabling post-application content printing on the labels, including techniques such as silk screening, laser etching, and color printing. This reduces the occurrence of rework and material waste, as labels can be easily updated or replaced when necessary.

In these ways, the label support structure may conserve an amount of resources used to support a market consuming a module assembly including the label support structure (e.g., raw materials, semiconductor manufacturing tools, labor, and/or computing resources).

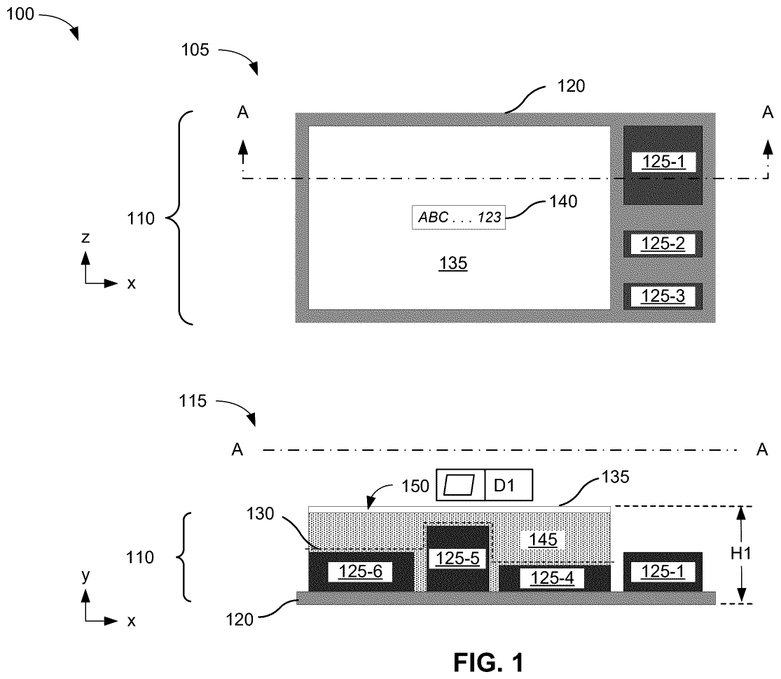

FIG. 1 is an example integrated assembly including a label support structure described herein. FIG. 1 includes a top view 105 of a module assembly 110 and a side section-view 115 (e.g., a section-view along section line A-A) of the module assembly 110. The module assembly 110 may be a memory module (e.g., a singled sided memory module or a double sided memory module), a solid state drive (SSD) module, a central processing unit (CPU) module, a motherboard module, a networking module, a microcontroller module, a communication module, or a driver module, among other examples.

As shown in FIG. 1, the module assembly 110 includes a substrate 120 (e.g., an interposer). The substrate 120 may be a multi-layer substrate that includes a combination of dielectric layers and conductive layers that are interspersed with one another in a vertically-arranged stack. For example, and in some implementations, the substrate 120 corresponds to a printed circuit board (PCB) type of substrate that includes dielectric layers having fiberglass-reinforced epoxy resin material interspersed with conductive layers having a metal material such as a copper material or an aluminum material, among other examples. As another example, and in some implementations, the substrate 120 corresponds to an interposer type of substrate that includes dielectric layers having a ceramic material interspersed with conductive layers having a metal material such as a silver material or a gold material, among other examples.

As further shown in FIG. 1, the module assembly 110 is populated with semiconductor packages 125 (e.g., the semiconductor packages 125-1 through 125-6). One or more of the semiconductor packages 125 may be a ball grid array (BGA) type of semiconductor package, a wafer level chip scale package (WLCSP) type of semiconductor package, a system in package (SiP) type of semiconductor package, a flip chip ball grid array (FCBGA) type of semiconductor package, a quad flat package (QFP), or a thin small outline package (TSOP) type of semiconductor package, among other examples. In some implementations, each of the semiconductor packages 125 includes a casing (e.g., an epoxy mold compound) that encapsulates at least one integrated circuit die. The integrated circuit die may include a memory device such as a DRAM memory device or a NAND memory device, among other examples. Additionally, or alternatively, the integrated circuit die may include a logic device, a processor, a power management device, an inductor device, or a voltage regulator device, among other examples. The semiconductor packages 125 (e.g., electronic components) may be mounted and/or connected with pads of the module assembly 110.

Two or more of the semiconductor packages 125 may have different heights (e.g., top surfaces that are different distances from the substrate 120). For example, and as shown in the side section-view 115, the height of the semiconductor package 125-5 is greater than the height of the semiconductor die package 125-6, and the height of the semiconductor package 125-6 is greater than the height of the semiconductor package 125-4. The different heights may form an uneven topography 130 across at least a portion of the module assembly 110.

As further shown in FIG. 1, a label 135 may be over the substrate 120 and overlap one or more of the semiconductor packages 125 (e.g., as shown in side section-view 115, the label 135 is over the semiconductor packages 125-4, 125-5, and 125-6). The label 135 may include printed content 140 such as textual content (e.g., part descriptions, part numbers, manufacturing dates), barcodes, QR codes, and/or graphical content, among other examples.

As further shown in FIG. 1, a label support structure 145 may be over the substrate 120. Additionally, or alternatively, the label support structure 145 may be between the substrate 120 and the label 135.

The label support structure 145 includes filler material. In some implementations, the filler material is a dimensionally stable filler material. The dimensionally stable filler material may not undergo significant expansion and/or contraction with changes in temperature, humidity, or other environmental factors. Examples of the dimensionally stable filler material that may be included in the label support structure 145 include epoxy resin, polyurethane resin, or a thermoplastic material.

Alternatively, and in some implementations, the filler material is an expandable filler material. The expandable filler material may include substances designed to fill voids or gaps in various applications, expanding to conform to the surrounding space upon activation. Often composed of polymers or foams, expandable filler materials come in various forms, including sheets, beads, or liquid formulations. When triggered by factors such as heat, moisture, or chemical reaction, the filler materials undergo expansion, increasing in volume and density to effectively seal or fill the designated area. Examples of the expandable filler material include graphene aerogel, ceramic foam, or polyimide foam.

As part of the label support structure 145, the filler material may have electrically insulative properties (e.g., have a resistivity that is greater than approximately 10⁸ ohm-meters). Additionally, or alternatively and in some implementations, the filler material has electromagnetic shielding properties for a given application (e.g., the filler material is capable of attenuating or blocking electromagnetic radiation across a specified frequency range of integrated circuitry included in the semiconductor packages 125). Additionally, or alternatively and in some implementations, the filler material is thermally-conductive (e.g., has a thermal conductivity greater than approximately 1 watt per meter Kelvin (W/m·K), which is substantially greater than the thermal conductivity of air (approximately 0.03 W/m·K)).

In some implementations, the label support structure 145 (e.g., one or more portions of the label support structure 145) is between at least one of the semiconductor packages 125 and the label 135. For example, and as shown in side section-view 115, the label support structure 145 is between semiconductor packages 125-4 through 125-6 and the label 135.

Additionally, or alternatively and in some implementations, the label support structure 145 (e.g., one or more portions of the label support structure 145) conforms to top surfaces of two or more semiconductor packages having different heights (e.g., different thicknesses). For example, and as shown in side section-view 115, the label support structure conforms to top surfaces of the semiconductor packages 125-4 through 125-6, which each have a different height. In other words, the label support structure 145 conforms to the uneven topography 130.

Additionally, or alternatively and in some implementations, the label support structure 145 surrounds (e.g., is over and/or along) one or more surfaces of semiconductor packages populating the substrate 120. For example, and as shown in side section-view 115, the label support structure 145 surrounds one or more surfaces of the semiconductor packages 125-4 through 125-6.

As shown in FIG. 1, the label support structure 145 includes a top surface 150 that may be conjoined with the label 135. The top surface 150 may be a substantially planar surface. For example, a flatness D1 (e.g., a variation in height across a labeling zone) of the top surface 150 may less than or equal to approximately 0.35 millimeters (mm). If the flatness D1 is greater than approximately 0.35 mm, an ability of a scanning tool (e.g., an optical character recognition (OCR) tool) to recognize the printed content 140 may be decreased). However, other values and/or ranges for the flatness D1 are within the scope of the present disclosure.

The top surface 150 may enable the label support structure 145 to satisfy one or more additional labeling thresholds. For example, and in some implementations, the top surface 150 may provide an adhesion area that satisfies an adhesion area threshold (e.g., an adhesion area provided by the top surface may be greater than approximately 40% of an area of the label 135). Additionally, or alternatively, the top surface 150 may provide support to the label 135 and satisfy an overhang threshold (e.g., the label 135 may extend not more than approximately 3.5 mm beyond an edge of the top surface 150). However, other values and ranges for the adhesion area threshold and the overhang threshold are within the scope of the present disclosure.

The label support structure 145 may enable the module assembly 110 to satisfy an overall height threshold (e.g., a thickness that is physically compatible with an end-use system). For example, and in a case where the module assembly 110 is an SSD assembly, an overall height H1 (e.g., thickness) may be less than approximately 1.5 mm. As another example, and in a case where the module assembly 110 is a single sided memory module, the overall height H1 may be less than approximately 1.18 mm. As another example, and in the case where the module assembly 110 is a doubled sided memory module, the overall height may be less than approximately 1.95 mm. However, other values and/or ranges for the overall height H1 are within the scope of the present disclosure.

As indicated above, FIG. 1 is an example. Other examples may differ from what is described with regard to FIG. 1.

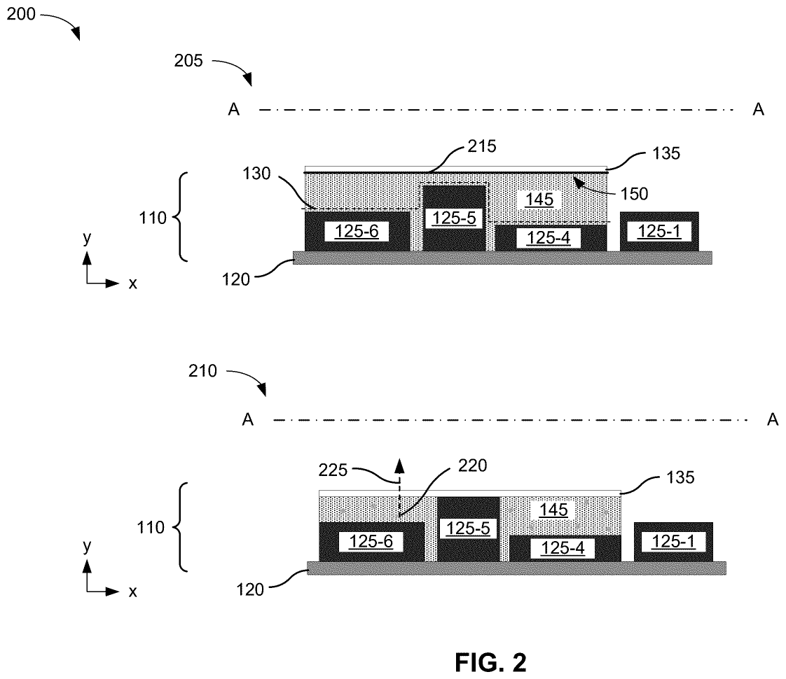

FIG. 2 includes diagrammatic views of example implementations 200 of a label support structure (e.g., the label support structure 145) described herein. Details of the example implementations are shown in side section-view 205 and side section-view 210 of FIG. 2.

As shown in side section-view 205, and in some implementations, an interface layer 215 is on the top surface 150 of the label support structure 145 (e.g., between the top surface 150 and the label 135). In some implementations, the interface layer 215 may be an adhesive layer that is configured to be conjoined with the label 135. Additionally, or alternatively, the interface layer 215 may be chemically or mechanically removable to facilitate removal and replacement of the label 135, thereby improving rework and/or recovery operations for a product which may be mis-labeled or need updated printed content (e.g., the printed content 140).

As shown in side section-view 210, and in some implementations, the label support structure 145 includes a composite material that includes a matrix material infused with thermally-conductive particulates 220. For example, the label support structure 145 may include graphene aerogel, ceramic foam, or polyimide foam (e.g., a matrix material) infused with nanotubes (e.g., the thermally-conductive particulates 220), among other examples. The matrix material infused with the thermally-conductive particulates 220 may increase a thermal conductivity of the label support structure 145. Increasing the thermal conductivity may increase heat flow 225 from the module assembly to satisfy or more thresholds related to junction temperatures of integrated circuitry included in the semiconductor packages 125, thereby improving a performance and/or a reliability of the module assembly 110.

As indicated above, FIG. 2 is provided as one or more examples. Other examples may differ from what is described with regard to FIG. 2.

As described in connection with FIGS. 1 and 2, and in some implementations, a semiconductor device assembly (e.g., the module assembly 110) includes a substrate (e.g., the substrate 120) populated with one or more semiconductor packages (e.g., the semiconductor packages 125). The semiconductor device assembly includes a label support structure (e.g., the label support structure 145) that includes an expandable filler material over the substrate.

Additionally, or alternatively and in some implementations, an integrated assembly (e.g., the module assembly 100) includes a substrate (e.g., the substrate 120) supporting a plurality of electronic components (e.g., the semiconductor packages 125) with varying heights that define an uneven topography (e.g., the uneven topography 130). The integrated assembly includes an expandable filler material (e.g., the label support structure 145) that is disposed over at least a subset of the plurality of electronic components, conforms to the uneven topography, and includes a substantially planar surface (e.g., the top surface 150). The integrated assembly includes a label (e.g., the label 135) conjoined with at least a portion of the substantially planar surface. In these ways, a flatness and readability of the label may be improved.

Furthermore, aspects of thermal management, electromagnetic shielding, and/or rework processes may be improved. As a result, the implementations may conserve an amount of resources used to support a market consuming the semiconductor device assembly and/or the integrated assembly (e.g., raw materials, semiconductor manufacturing tools, labor, and/or computing resources).

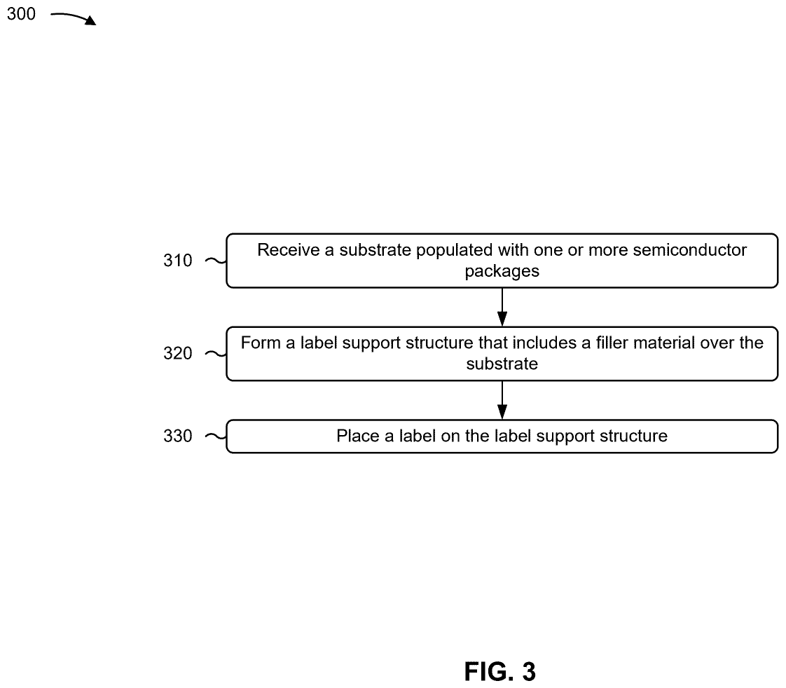

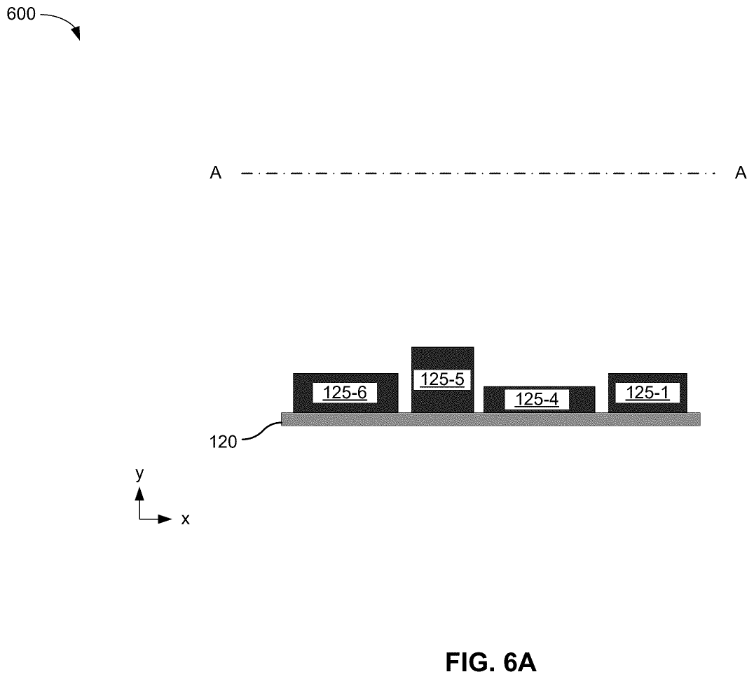

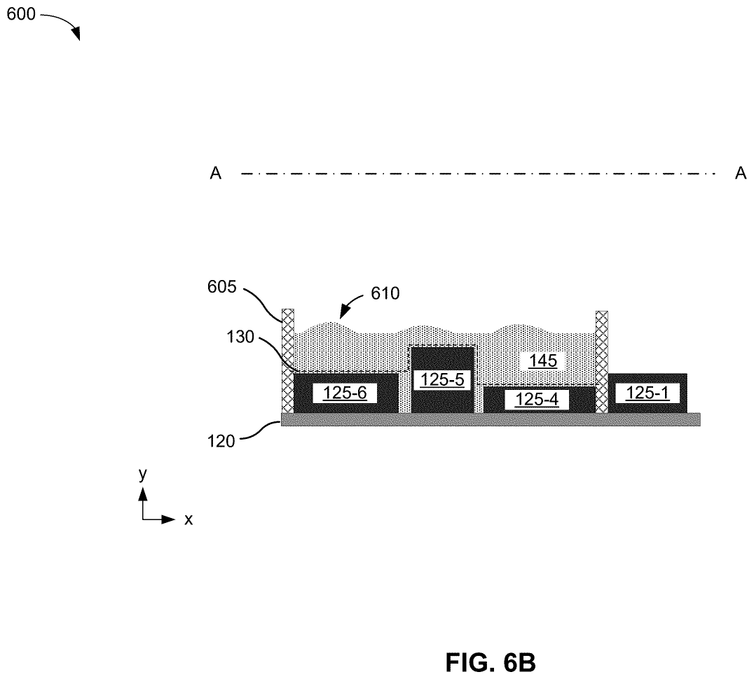

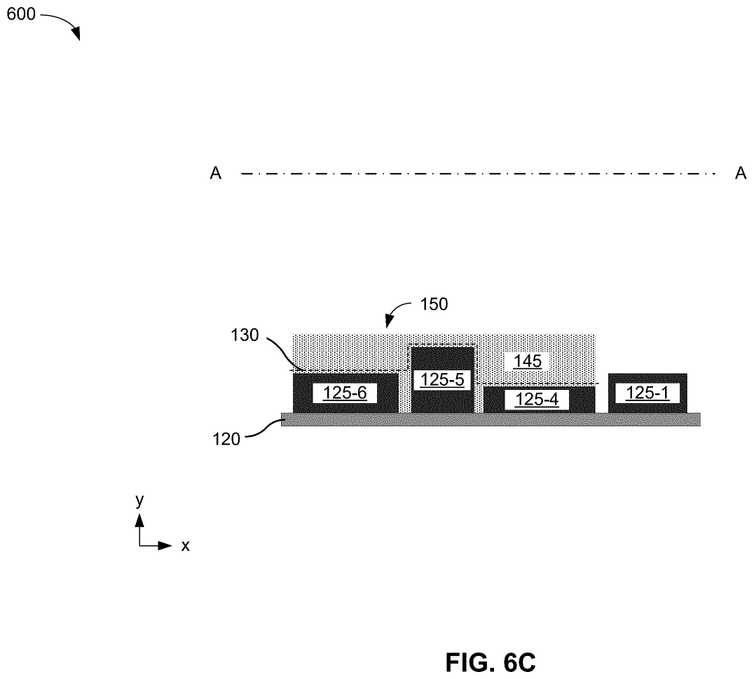

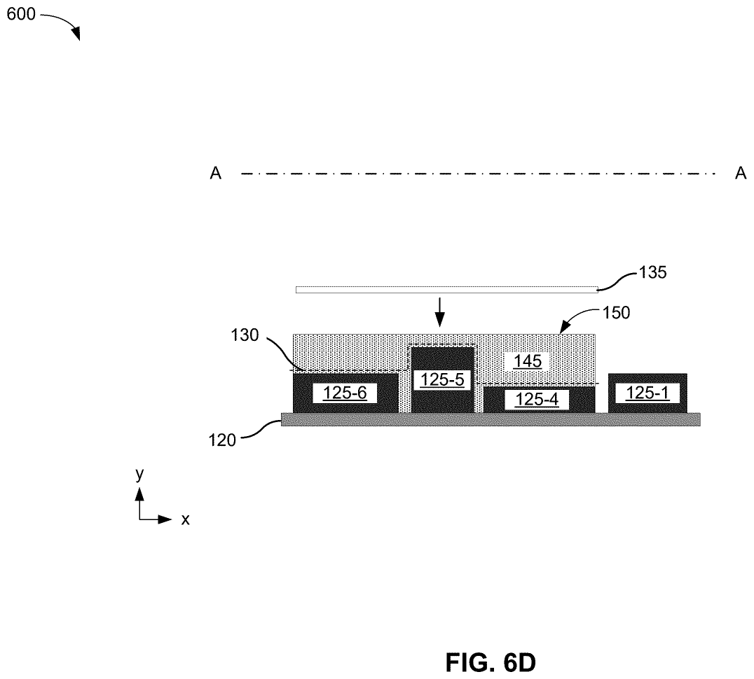

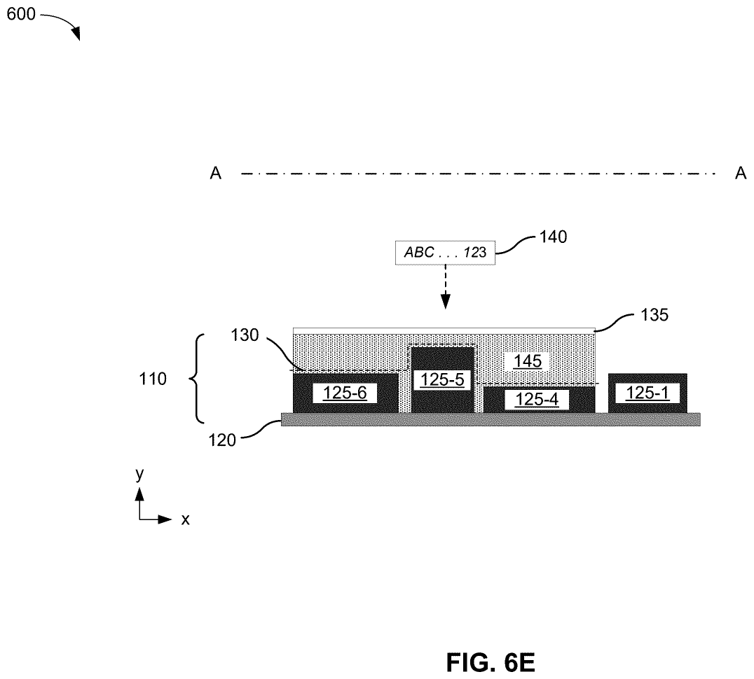

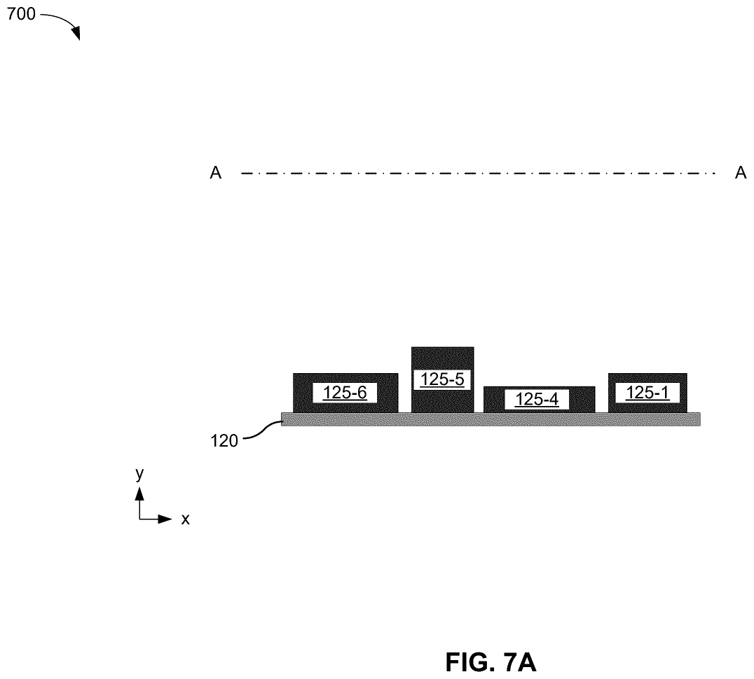

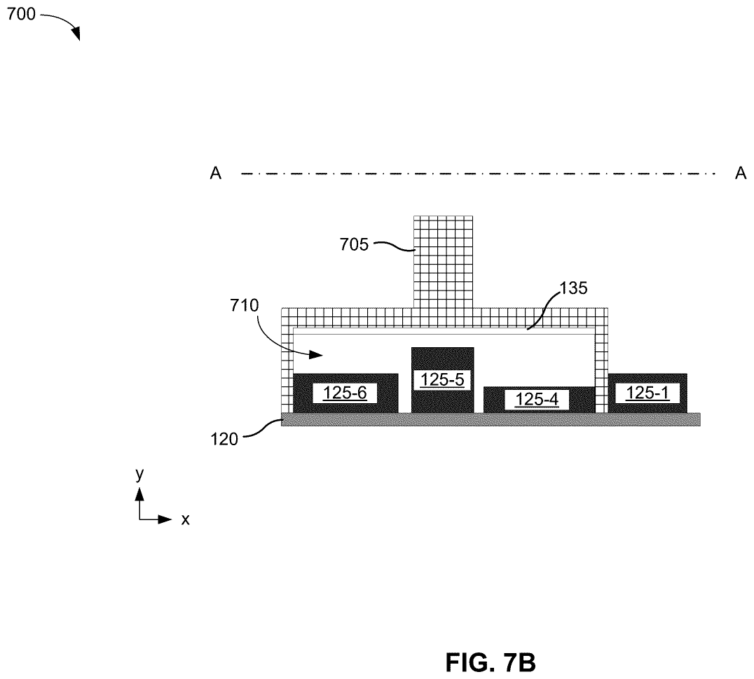

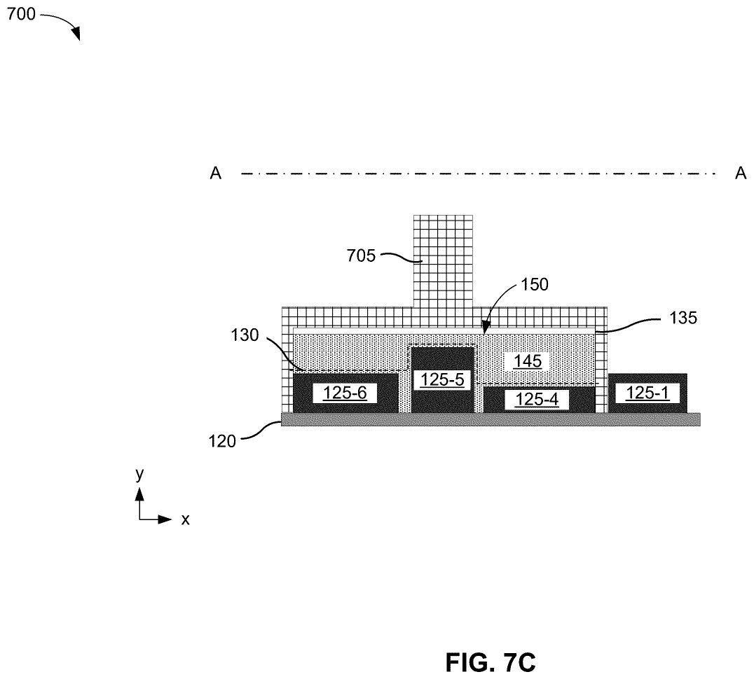

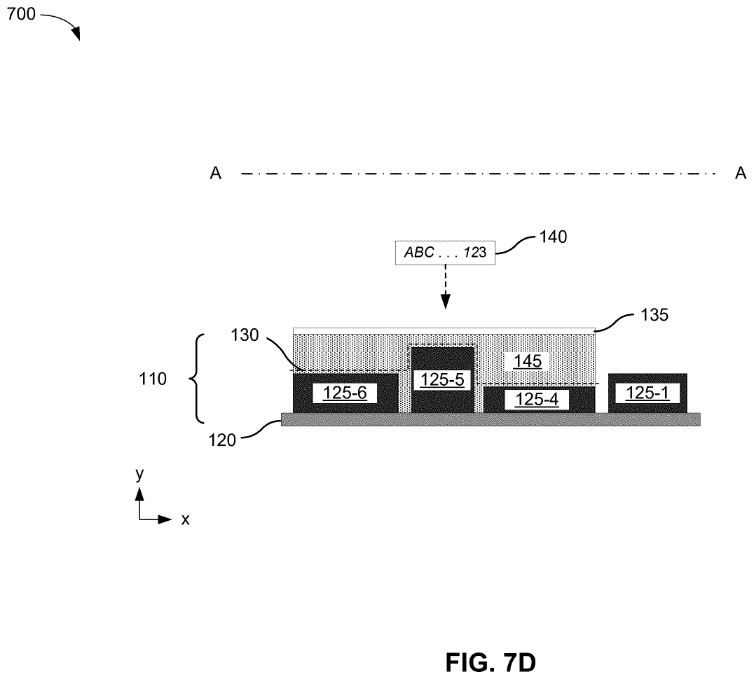

FIG. 3 is a flowchart of an example method 300 of forming an integrated assembly or memory device having a label support structure (e.g., the label support structure 145) including a filler material. In some implementations, and as described in greater detail in connection with FIGS. 6A-7D, one or more process blocks of FIG. 3 may be performed by various semiconductor manufacturing equipment.

As shown in FIG. 3, the method 300 may include receiving a substrate (e.g., the substrate 120) populated with one or more semiconductor packages (e.g., the semiconductor packages 125) (block 310). As further shown in FIG. 3, the method 300 may include forming a label support structure (e.g., the label support structure 145) that includes a filler material over the substrate (block 320). As further shown in FIG. 3, the method 300 may include placing a label (e.g., the label 135) on the label support structure (block 330).

The method 300 may include additional aspects, such as any single aspect or any combination of aspects described below and/or in connection with one or more other methods described elsewhere herein.

In a first aspect, forming the label support structure includes forming the label support structure using a dispense operation that dispenses the filler material in a liquid form. In some implementations, the filler material in the liquid form includes a viscosity that enables self-leveling of the liquid material.

In a second aspect, alone or in combination with the first aspect, forming the label support structure includes planarizing the label support structure to form a substantially planar surface (e.g., the top surface 150).

In a third aspect, alone or in combination with one or more of the first and second aspects, planarizing the label support structure includes planarizing the label support structure using a curing process. In some implementations, the curing process uses a chemical agent that promotes a reaction that fills in gaps and irregularities in the label support structure.

In a fourth aspect, alone or in combination with one or more of the first through third aspects, planarizing the label support structure includes planarizing the label support structure using a mechanical planarization process.

In a fifth aspect, alone or in combination with one or more of the first through fourth aspects, forming the label support structure includes curing the filler material using ultraviolet light.

In a sixth aspect, alone or in combination with one or more of the first through fifth aspects, forming the label support structure includes curing the filler material using a thermal curing operation.

In a seventh aspect, alone or in combination with one or more of the first through sixth aspects, using the thermal curing operation includes using heat provided from a chuck presenting the label.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming an integrated assembly that includes the label support structure 145, any part described herein of the label support structure 145, and/or any part described herein of an integrated assembly that includes the label support structure 145. For example, the method 300 may include forming one or more of the module assembly 110, the substrate 120, and/or the label 135.

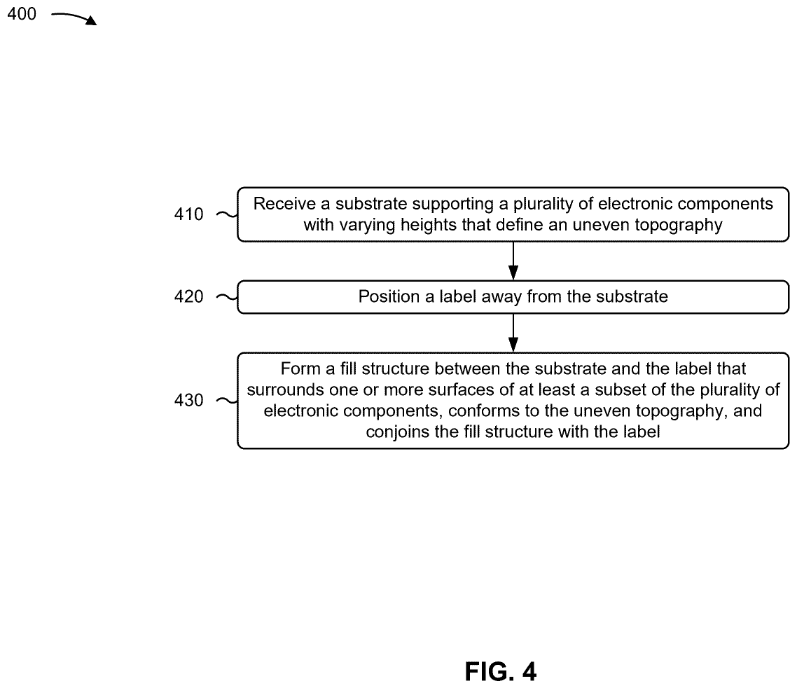

FIG. 4 is a flowchart of an example method 400 of forming an integrated assembly or memory device having a label support structure (e.g., the label support structure 145) including a filler material. In some implementations, and as described in greater detail in connection with FIGS. 6A-7D, one or more process blocks of FIG. 4 may be performed by various semiconductor manufacturing equipment.

As shown in FIG. 4, the method 400 may include receiving a substrate (e.g., the substrate 120) supporting a plurality of electronic components (e.g., the semiconductor packages 125) with varying heights that define an uneven topography (e.g., the uneven topography 130) (block 410). As further shown in FIG. 4, the method 400 may include positioning a label (e.g., the label 135) away from the substrate (block 420). As further shown in FIG. 4, the method 400 may include forming a fill structure (e.g., the label support structure 145) between the substrate and the label that surrounds one or more surfaces of at least a subset of the plurality of electronic components, conforms to the uneven topography, and conjoins the fill structure with the label (block 430).

The method 400 may include additional aspects, such as any single aspect or any combination of aspects described below and/or in connection with one or more other methods described elsewhere herein.

In a first aspect, positioning the label away from the substrate includes positioning the label using a chuck component.

In a second aspect, alone or in combination with the first aspect, using the chuck component includes using a vacuum to secure the label against the chuck component, or using an adhesive to secure the label against the chuck component.

In a third aspect, alone or in combination with one or more of the first and second aspects, forming the fill structure between the substrate and the label includes forming a substantially planar interface (e.g., the top surface 150) against the label.

In a fourth aspect, alone or in combination with one or more of the first through third aspects, the method 400 includes printing content (e.g., the content 140) on the label after placing the label on the fill structure.

In a fifth aspect, alone or in combination with one or more of the first through fourth aspects, printing content on the label includes printing content on the label using a silk screen operation, printing content on the label using a laser etching operation, or printing content on the label using a color printing operation.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming an integrated assembly that includes the label support structure 145, any part described herein of the label support structure 145, and/or any part described herein of an integrated assembly that includes the label support structure 145. For example, the method 400 may include forming one or more of the module assembly 110, the substrate 120, and/or the label 135.

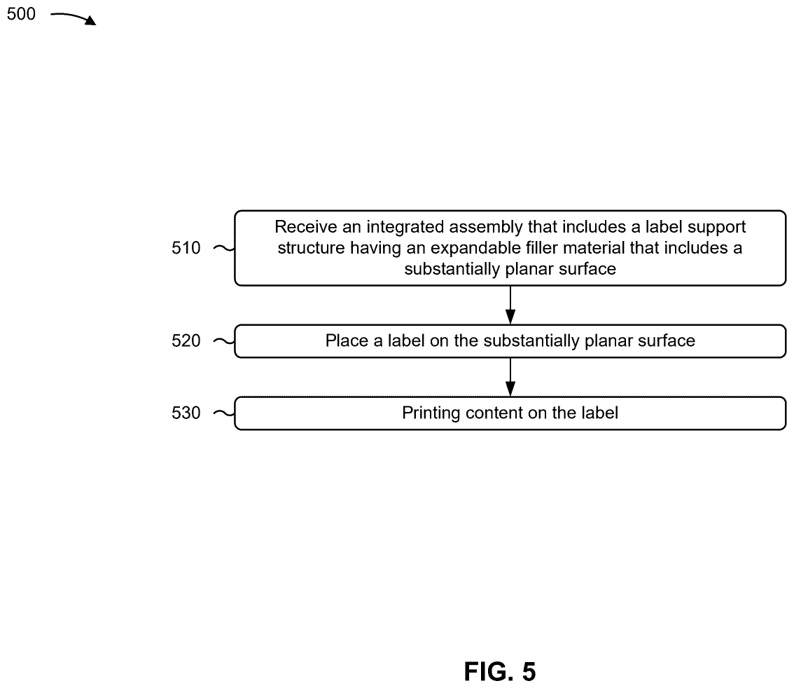

FIG. 5 is a flowchart of an example method 500 of forming an integrated assembly or memory device having a label support structure (e.g., the label support structure 145) including a filler material. In some implementations, and as described in greater detail in connection with FIGS. 6A-7D, one or more process blocks of FIG. 5 may be performed by various semiconductor manufacturing equipment.

As shown in FIG. 5, the method 500 may include receiving an integrated assembly (e.g., the substrate 120 populated with the semiconductor packages 125) that includes a label support structure (e.g., the label support structure 145) having an expandable filler material that includes a substantially planar surface (e.g., the top surface 150) (block 510). As further shown in FIG. 5, the method 500 may include placing a label on the substantially planar surface (block 520). As further shown in FIG. 5, the method 500 may include printing content on the label (block 530).

The method 500 may include additional aspects, such as any single aspect or any combination of aspects described below and/or in connection with one or more other methods described elsewhere herein.

Although FIG. 5 shows example blocks of the method 500, in some implementations, the method 500 may include additional blocks, fewer blocks, different blocks, or differently arranged blocks than those depicted in FIG. 5. In some implementations, the method 300 may include forming an integrated assembly that includes the label support structure 145, any part described herein of the label support structure 145, and/or any part described herein of an integrated assembly that includes the label support structure 145. For example, the method 500 may include forming one or more of the module assembly 110, the substrate 120, and/or the label 135.

FIGS. 6A-6E are diagrammatic views showing formation of an integrated assembly (e.g., the module assembly 110) having a label support structure (e.g., the label support structure 145) including a filler material at example process stages of an example process 600 of forming the integrated assembly.

As shown in FIG. 6A, the process 600 may include receiving the substrate 120 populated with the semiconductor packages 125 (e.g., the semiconductor packages 125-1, 125-4, 125-5, and 125-6 as shown in side section-view of FIG. 6A). In other words, the process 600 includes receiving the substrate 120 supporting a plurality of electronic components. In some implementations, the semiconductor packages 125 are electrically coupled with traces of the substrate 120 through a surface mount (SMT) process that uses a combination of semiconductor tools such as a solder printing tool, a pick-and-place tool, and a reflow tool, among other examples.

As shown in FIG. 6B, the process 600 may include forming the label support structure 145. In some implementations, and as shown in FIG. 6B, forming the label support structure 145 includes using a dam-and-fill operation, where a semiconductor tool such as a dispense tool uses dam structures 605 to contain and/or shape a filler material that is dispensed in liquid form. The filler material may be an expandable filler material or a dimensionally-stable filler material as described in connection with FIG. 1 and elsewhere herein.

As further shown in FIG. 6B, the filler material may conform with the uneven topography 130 and fill in gaps between the semiconductor packages 125. Furthermore, and in some implementations, forming the label support structure 145 includes forming anomalies 610 (e.g., gaps and/or irregularities) along a top surface of the label support structure 145.

As shown in FIG. 6C, the process 600 may include planarizing the label support structure 145 to form the top surface 150. In some implementations, planarizing the label support structure 145 relies on a viscosity of the dispensed filler material (e.g., in liquid form) to self-level the label support structure 145 using gravity.

In some implementations, and either prior to planarizing the label support structure 145 or as part of planarizing the label support structure 145, the process 600 includes curing the label support structure 145. As an example, curing the label support structure 145 may include using a thermal curing operation, during which an oven tool provides heat to the label support structure 145. Additionally, or alternatively, curing the label support structure 145 may include using an ultraviolet light curing operation, during which an ultraviolet lamp tool emits ultraviolet light upon the label support structure 145. Additionally, or alternatively, curing the label support structure 145 may include using a chemical agent that promotes a reaction with the filler material to cure the filler material and fill in gaps and irregularities in the label support structure 145.

In some implementations, and after curing of the label support structure 145, a planarization tool performs a planarization operation to planarize the label support structure 145 and form the top surface 150. The planarization operation may be a chemical mechanical planarization operation or another suitable planarization operation, among other examples.

As shown in FIG. 6D, the process 600 may include placing the label 135 on the label support structure 145. As an example, a pick-and-place tool may perform a pick-and-place operation and conjoin the label 135 with the top surface 150. Conjoining the label 135 with the top surface 150 may include using an adhesive that is on the label 135 and/or the top surface 150.

In some implementations, and in a case where the label support structure 145 is in an uncured state (e.g., not cured using one or more curing operations as described in connection with FIG. 6C), placing the label 135 on the label support structure 145 may activate curing of the label support structure 145. For example, the label 135 may include a catalyst that reacts with the filler material to cure the label support structure 145.

As shown in FIG. 6E, the process 600 may include printing the content 140 on the label 135. As an example, a printing tool may perform a silk screening operation, a laser etching operation, or a color printing operation to print the content 140 on the label 135. Printing the content 140 may include printing textual content (e.g., part descriptions, part numbers, manufacturing dates), barcodes, QR codes, and/or graphical content, among other examples.

As indicated above, the process steps described in connection with FIGS. 6A-6E are provided as examples. Other examples may differ from what is described with respect to FIGS. 6A-6E. Furthermore, the structure shown in FIG. 6E may be equivalent to the module assembly 110 including the label support structure 145 described elsewhere herein.

FIGS. 7A-7D are diagrammatic views showing formation of an integrated assembly having a label support structure including a filler material at example process stages of an example process of forming the integrated assembly.

As shown in FIG. 7A, the process 700 may include receiving the substrate 120 populated with the semiconductor packages 125 (e.g., the semiconductor packages 125-1, 125-4, 125-5, and 125-6 as shown in side section-view of FIG. 7A). In other words, the process 700 includes receiving the substrate 120 supporting a plurality of electronic components. In some implementations, the semiconductor packages 125 are electrically coupled with traces of the substrate 120 through a surface mount (SMT) process that uses a combination of semiconductor tools such as a solder printing tool, a pick-and-place tool, and a reflow tool, among other examples.

As shown in FIG. 7B, the process 700 may include positioning the label 135 away from the substrate 120. In some implementations, positioning label 135 away from the substrate 120 includes positioning the label 135 such that the label 135 is above the substrate 120 and overlaps one or more of the semiconductor packages 125 (e.g., the semiconductor packages 125-4, 126-5, and 125-6).

Positioning the label 135 away from the substrate 120 may include securing the label 135 to a surface of a chuck component 705. In some implementations, the chuck component 705 uses vacuum to secure the label 135 against the surface. Alternatively, the chuck component 705 may use an adhesive to secure the label 135 against the surface. In some implementations, the chuck component 705 corresponds to a portion of a die or a mold of an injection molding tool. In some implementations, the chuck component 705 corresponds to a portion of a die or a mold of a transfer molding tool.

Positions of the chuck component 705 may be controlled and/or changed to position the label 135 away from the substrate 120. In some implementations, positioning the label 135 away from the substrate 120 includes engaging protrusions and/or edges of the chuck component 705 against a surface of the substrate 120 to form a sealed void 710. The sealed void 710 may surround the semiconductor packages 125.

As shown in FIG. 7C, the process 700 may include forming the label support structure 145. Forming the label support structure 145 may include using an injection operation, a dispense operation, or another suitable operation to fill the void 710 with a filler material. The filler material may be an expandable filler material or a dimensionally-stable filler material as described in connection with FIG. 1 and elsewhere herein.

The filler material may conform to the uneven topography 130 and fill in gaps between the semiconductor packages 125. Additionally, or alternatively, the filler material may form a substantially planar interface (e.g., the top surface 150) against the label 135. Additionally, or alternatively, the filler material may conjoin with the label 135.

The process 700 may include curing the label support structure 145. As an example, and in some implementations, conjoining the filler material with the label 135 activates curing of the label support structure 145. In such a case, the label 135 may include a catalyst that reacts with the filler material to cure the label support structure 145. Alternatively, and in some implementations, curing the label support structure 145 includes using a thermal curing operation. In such a case, heat may be provided through the chuck component 705 to cure the label support structure 145.

As shown in FIG. 7D, the process 700 may include printing the content 140 on the label 135. As an example, a printing tool may perform a silk screening operation, a laser etching operation, or a color printing operation to print the content 140 on the label 135. Printing the content 140 may include printing textual content (e.g., part descriptions, part numbers, manufacturing dates), barcodes, QR codes, and/or graphical content, among other examples.

As indicated above, the process steps described in connection with FIGS. 7A-7D are provided as examples. Other examples may differ from what is described with respect to FIGS. 7A-7D. Furthermore, the structure shown in FIG. 7D may be equivalent to the module assembly 110 including the label support structure 145 described elsewhere herein.

Although FIGS. 6A-7D describe techniques of forming a label support structure (e.g., the label support structure 145) using operations that include dispensing and/or injecting a filler material over and/or around semiconductor packages supported by a substrate (e.g., the semiconductor packages 125 supported by the substrate 120), other techniques may be used. For example, and in some implementations, the label support structure may be “pre-formed” using a separate molding process and subsequently affixed to the substrate.

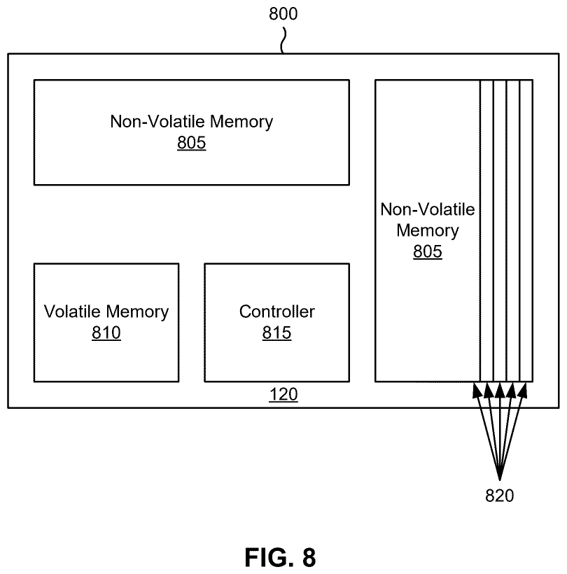

FIG. 8 is a diagram of an example memory device 800 that may be manufactured using techniques described herein. The memory device 800 is an example of the module assembly 110 described above in connection with FIG. 1, including the label support structure 145. The memory device 800 may be any electronic device configured to store data in memory. In some implementations, the memory device 800 may be an electronic device configured to store data persistently in non-volatile memory 805. For example, the memory device 800 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 800 may include non-volatile memory 805, volatile memory 810, and a controller 815. The components of the memory device 800 may be mounted on or otherwise disposed on the substrate 120. In some implementations, the non-volatile memory 805 includes a single die. Additionally, or alternatively, the non-volatile memory 805 may include multiple dies, such as stacked semiconductor dies 820 (e.g., in a straight stack, a shingle stack, or another type of stack).

The non-volatile memory 805 may be configured to maintain stored data after the memory device 800 is powered off. For example, the non-volatile memory 805 may include NAND memory or NOR memory. The volatile memory 810 may require power to maintain stored data and may lose stored data after the memory device 800 is powered off. For example, the volatile memory 810 may include one or more latches and/or RAM, such as DRAM and/or SRAM. As an example, the volatile memory 810 may cache data read from or to be written to non-volatile memory 805, and/or may cache instructions to be executed by the controller 815.

The controller 815 may be any device configured to communicate with the non-volatile memory 805, the volatile memory 810, and a host device (e.g., via a host interface of the memory device 800). For example, the controller 815 may include a memory controller, a system controller, an ASIC, an FPGA, a processor, a microcontroller, and/or one or more processing components. In some implementations, the memory device 800 may be included in a system that includes the host device. The host device may include one or more processors configured to execute instructions and store data in the non-volatile memory 805.

The controller 815 may be configured to control operations of the memory device 800, such as by executing one or more instructions (sometimes called commands). For example, the memory device 800 may store one or more instructions as firmware, and the controller 815 may execute those one or more instructions. Additionally, or alternatively, the controller 815 may receive one or more instructions from a host device via a host interface, and may execute those one or more instructions. For example, the controller 815 may transmit signals to and/or receive signals from the non-volatile memory 805 and/or the volatile memory 810 based on the one or more instructions, such as to transfer data to (e.g., write or program), to transfer data from (e.g., read), and/or to erase all or a portion of the non-volatile memory 805 (e.g., one or more memory cells, pages, sub-blocks, blocks, or planes of the non-volatile memory 805).

As indicated above, FIG. 8 is provided as an example. Other examples may differ from what is described with regard to FIG. 8. The number and arrangement of components shown in FIG. 8 are provided as an example. In practice, there may be additional components, fewer components, different components, or differently arranged components than those shown in FIG. 8.

In some implementations, a semiconductor device assembly includes a substrate populated with one or more semiconductor packages; and a label support structure that includes an expandable filler material over the substrate.

In some implementations, an integrated assembly includes a substrate supporting a plurality of electronic components with varying heights that define an uneven topography; an expandable filler material that is disposed over at least a subset of the plurality of electronic components, conforms to the uneven topography, and includes a substantially planar surface; and a label conjoined with at least a portion of the substantially planar surface.

In some implementations, a method includes receiving a substrate populated with one or more semiconductor packages; forming a label support structure that includes a filler material over the substrate; and placing a label on the label support structure.

In some implementations, a method includes receiving a substrate supporting a plurality of electronic components with varying heights that define an uneven topography; positioning a label away from the substrate; and forming a fill structure between the substrate and the label that surrounds one or more surfaces of at least a subset of the plurality of electronic components, conforms to the uneven topography, and conjoins the fill structure with the label.

In some implementations, a method includes receiving an integrated assembly that includes a label support structure having an expandable filler material that includes a substantially planar surface; placing a label on the substantially planar surface; and printing content on the label.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate populated with one or more semiconductor packages; and
a label support structure that includes an expandable filler material over the substrate.

2. The semiconductor device assembly of claim 1, wherein the expandable filler material comprises at least one of:
graphene aerogel,
ceramic foam, or
polyimide foam.

3. The semiconductor device assembly of claim 1, wherein the label support structure comprises:
a material having one or more properties that provide electromagnetic shielding to the one or more semiconductor packages.

4. The semiconductor device assembly of claim 1, wherein the expandable filler material comprises:
a material with electrically insulative properties.

5. The semiconductor device assembly of claim 1, wherein a top surface of the label support structure is configured to be conjoined with a label.

6. The semiconductor device assembly of claim 1, further comprising:
an interface layer on a top surface of the label support structure that is configured to be conjoined with a label.

7. The semiconductor device assembly of claim 6, wherein the interface layer is chemically or mechanically removable to facilitate removal and replacement of the label.

8. An integrated assembly, comprising:
a substrate supporting a plurality of electronic components with varying heights that define an uneven topography;
an expandable filler material that is disposed over at least a subset of the plurality of electronic components, conforms to the uneven topography, and includes a substantially planar surface; and
a label conjoined with at least a portion of the substantially planar surface.

9. The integrated assembly of claim 8, wherein the expandable filler material comprises:
a matrix material infused with thermally-conductive particulates.

10. The integrated assembly of claim 9, wherein the thermally-conductive particulates comprise nanotubes.

11. The integrated assembly of claim 8, wherein at least a portion of the label is conjoined with a top surface of at least one of the plurality of electronic components.

12. A method, comprising:
receiving a substrate populated with one or more semiconductor packages;
forming a label support structure that includes a filler material over the substrate; and
placing a label on the label support structure.

13. The method of claim 12, wherein forming the label support structure includes:
forming the label support structure using a dispense operation that dispenses the filler material in a liquid form,
wherein the filler material in the liquid form includes a viscosity that enables self-leveling of the filler material.

14. The method of claim 12, wherein forming the label support structure includes:
planarizing the label support structure to form a substantially planar surface.

15. The method of claim 14, wherein planarizing the label support structure includes:
planarizing the label support structure using a curing process,
wherein the curing process uses a chemical agent that promotes a reaction with the filler material to fills in gaps and irregularities in the label support structure.

16. The method of claim 14, wherein planarizing the label support structure includes:
planarizing the label support structure using a chemical mechanical planarization operation.

17. The method of claim 12, wherein forming the label support structure includes:
curing the filler material using ultraviolet light.

18. The method of claim 12, wherein forming the label support structure includes:
curing the filler material using a thermal curing operation.

19. The method of claim 18, wherein using the thermal curing operation includes:
using heat provided from a chuck presenting the label.

20. A method, comprising:
receiving a substrate supporting a plurality of electronic components with varying heights that define an uneven topography;
positioning a label away from the substrate; and
forming a fill structure between the substrate and the label that surrounds one or more surfaces of at least a subset of the plurality of electronic components, conforms to the uneven topography, and conjoins the fill structure with the label.

21. The method of claim 20, wherein positioning the label away from the substrate includes:
positioning the label using a chuck component.

22. The method of claim 21, wherein using the chuck component includes:
using a vacuum to secure the label against the chuck component, or
using an adhesive to secure the label against the chuck component.

23. The method of claim 21, wherein forming the fill structure between the substrate and the label includes:
forming a substantially planar interface against the label.

24. The method of claim 20, further comprising:
printing content on the label after placing the label on the fill structure.

25. The method of claim 22, wherein printing content on the label includes:
printing content on the label using a silk screen operation,
printing content on the label using a laser etching operation, or
printing content on the label using a color printing operation.
